(19) United States
(12) Patent Application Publication
(10) Pub. No.: US 2006/0045668 A1
(43) Pub. Date: Mar. 2, 2006

(54) System for handling of wafers within a process tool

(76) Inventor: Al W. Grabowski, Paradise Valley, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/184,511

(22) Filed: Jul. 18, 2005

Related U.S. Application Data
(60) Provisional application No. 60/589,412, filed on Jul. 19, 2004.

(51) Int. Cl. H01L 21/00

(52) U.S. Cl. 414/217

(57) ABSTRACT

A semiconductor process tool having a dual angled loadlock system, wherein a substrate path through each of the loadlock chambers is angled and biased toward one side through a gate valve. A wafer handling chamber is in selective communication with the loadlock chambers. The wafer handling chamber has a robot that is capable of accessing substrates in both of the loadlock chambers. A gate valve includes an insert within a wall separating the wafer handling chamber from one of the loadlocks, and a valve seat mounted on the insert and protruding into the wafer handling chamber.

### REFERENCE TO RELATED APPLICATION

The present application claims the priority benefit under 35 U.S.C. §119(e) to U.S. provisional application No. 60/589,412, filed Jul. 19, 2004.

### FIELD OF THE INVENTION

The present invention relates generally to semiconductor fabrication, and more particularly to improved wafer handling systems.

### BACKGROUND OF THE INVENTION

Semiconductor wafers or other such substrates typically arrive at the input of a process tool as a group carried in a wafer carrier and from this input must be transported among the internal stations of a process tool. In furtherance of this task, wafer handling systems facilitate the transfer of wafers from one station to another. During this process, it is very important that the wafer be isolated from contamination. The presence of contaminant particles on the surface of a wafer can lead to the formation of defects during the fabrication process. Therefore, the wafers must be moved between isolated interior chambers of a process tool in such a way as to minimize contamination of the wafers themselves as well as the possibility of cross-contamination of chambers.

In furtherance of minimizing wafer contamination, it is desirable to minimize the amount of time a wafer is exposed to contaminants. One way to minimize contaminants is to use standardized front opening unified pods (FOUPs).

Another approach to minimizing wafer exposure to the ambient environment (i.e., clean room) is to use a large capacity loadlock chamber (e.g., 25 wafers) capable of receiving an entire cassette or FOUP of wafers. However, large capacity loadlock chambers pose a number of problems, including requiring complex elevator mechanisms, which require an even larger volume. The elevator mechanisms require extra chamber “headroom” in order to have space to raise and lower the load of wafers, allowing access by single wafer robots. Due to the large internal volume of high capacity load lock chambers, longer purge cycles are necessary to remove potentially wafer damaging agents, such as oxygen and moisture. During these purge cycles, wafer processing is delayed while waiting on completion of the purging. In systems where two loadlock chambers are employed, the footprint of the fabrication tool can also increase substantially due to the addition of the second loadlock.

Wafer handling systems typically employ robot arms in order to effectively transfer wafers between stations. On the end of each of these arms, an end effector is typically configured to gain access to a wafer at a first station, lift the wafer, transport the wafer, gain access to the second station, and then deposit the wafer at the second station.

The cost of processing semiconductor wafers, always a prime consideration, is often evaluated by the throughput per unit of cost. Another measure of cost is the throughput per area of floor space, wherein it is desirable to reduce the footprint of the apparatus employed. Related to both is the importance of reducing the capital cost of the equipment. Also important is the ability to incorporate readily available standardized equipment on the market into variations of particular modules used within a process tool. Therefore, advancements that can improve the competitive edge by either measure are highly desirable.

### SUMMARY OF THE INVENTION

In accordance with one aspect of the present invention, a loadlock system is provided, comprising a first loadlock chamber having a first port and a second port, wherein a first axis is perpendicular to the first port and a second axis perpendicular to the second port. The first axis and the second axis form an acute angle. The loadlock system also comprises a second loadlock chamber having a third port and a fourth port, wherein a third axis is perpendicular to the third port and a fourth axis is perpendicular to a fourth port. The third axis and the fourth axis form an acute angle. The loadlock system also has a first wafer path from the first port to the second port, wherein the first wafer path through at least one of the first and second ports is off-centered with respect to side walls of the at least one of the first and second ports, and a second wafer path from the third port to the fourth port, wherein the second wafer path through at least one of the third and fourth ports is off-centered with respect to side walls of the at least one of the third and fourth ports.

In accordance with another aspect of the invention, a loadlock system is provided, comprising a first loadlock chamber having an inlet gate valve and an outlet gate valve at an angle to one another, and a second loadlock chamber having an inlet gate valve and an outlet gate valve at an angle to one another, wherein a gate valve of the first loadlock chamber is directly adjacent a gate valve of the second loadlock chamber.

According to another aspect of the invention, a loadlock chamber for transferring a semiconductor substrate therethrough, comprising an inlet port having a left side wall and a right side wall, an outlet port having a left side wall and a right side wall, and a path through the loadlock chamber from the inlet port to the outlet port along which the substrate travels. The path is angled such that the path through the inlet port forms an acute angle with the path through the outlet port, and the path is off-centered with respect to the left side wall and the right side wall of at least one of the inlet and outlet ports.

According to yet another aspect of the invention, a semiconductor process tool for processing a substrate, comprising an atmospheric front end module having a robot, and at least one loadlock chamber coupled to the atmospheric front end module. The loadlock chamber has an inlet and an outlet, a first axis perpendicular to the inlet and a second axis perpendicular to the outlet. The first axis and the second axis form an acute angle, and a substrate path through at least one of the inlet and outlet is biased with respect to the width of the at least one of the inlet and outlet. The process tool also comprises a wafer handling chamber having a robot. The wafer handling chamber is coupled to the loadlock chamber and at least one substrate processing chamber is coupled to the wafer handling chamber.

According to another aspect of the invention, a method of transferring a semiconductor substrate is provided. The substrate is transferred from a cassette loading dock to a loadlock chamber though a first gate valve. The substrate is then transferred from the loadlock chamber to a transfer chamber through a second gate valve, wherein the loadlock chamber has a substrate path along which the substrate travels from the first gate valve to the second gate valve. The substrate path through at least one of the gate valves is off-centered with respect to a width of an opening of the gate valve.

In accordance with another aspect of the invention, a semiconductor process tool is provided. The tool includes a transfer chamber having a first robot capable of transporting at least one substrate. A loadlock chamber abuts and is in selective communication with the transfer chamber. A wall separating the loadlock chamber from the transfer chamber has an opening therein, and an insert is aligned within the wall opening. A gate valve seat is mounted to the insert and extends from the insert into the transfer chamber.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1 is a schematic top plan view showing a section of a semiconductor process tool, constructed in accordance with a preferred embodiment of the present invention.

FIG. 2 is a schematic top plan view of the FOUPs, the atmospheric front end module, and the loadlock chambers of FIG. 1, showing access by the robot arm to one of the loadlock chambers.

FIG. 3A is a schematic top and front perspective view of a cassette rack on a front end loading dock, in accordance with a preferred embodiment, where the FOUP doors are not shown.

FIG. 3B is a schematic top and front perspective view of an embodiment employing a loadlock chamber having a support rack, in accordance with a preferred embodiment.

FIG. 4 is a top plan view of the right loadlock chamber from FIG. 1, in accordance with an embodiment of the present invention.

FIG. 5 is a front perspective view of a gate valve insert, in accordance with an embodiment.

FIG. 6 is a cross-sectional side view of the gate valve insert in relation to the loadlock chamber and the wafer handling chamber, in accordance with an embodiment.

FIG. 7A is a top perspective view of a Bernoulli wand end effector of a wafer handling robot of a preferred embodiment.

FIG. 7B is a top plan view of a Bernoulli wand end effector of a wafer handling robot of a preferred embodiment.

FIG. 7C is a side view of a Bernoulli wand end effector of a wafer handling robot of a preferred embodiment.

FIG. 8 is a process flow diagram of a preferred method of fabricating integrated circuits, in accordance with an embodiment of the present invention.

### DETAILED DESCRIPTION OF THE PREFERRED EMBODIMENT

The following detailed description of the preferred embodiments and methods presents a description of certain specific embodiments to assist in understanding the claims. However, one may practice the present invention in a multitude of different embodiments and methods as defined and covered by the claims.

Referring more specifically to the drawings for illustrative purposes, the present invention is embodied in the devices generally shown in the Figures. It will be appreciated that the apparatuses may vary as to configuration and as to details of the parts, and that the methods may vary as to the specific steps and sequence, without departing from the basic concepts as disclosed herein.

Referring more specifically to the drawings for illustrative purposes, the present invention is embodied in the devices generally shown in the Figures. It will be appreciated that the apparatuses may vary as to configuration and as to details of the parts without departing from the basic concepts as disclosed herein.

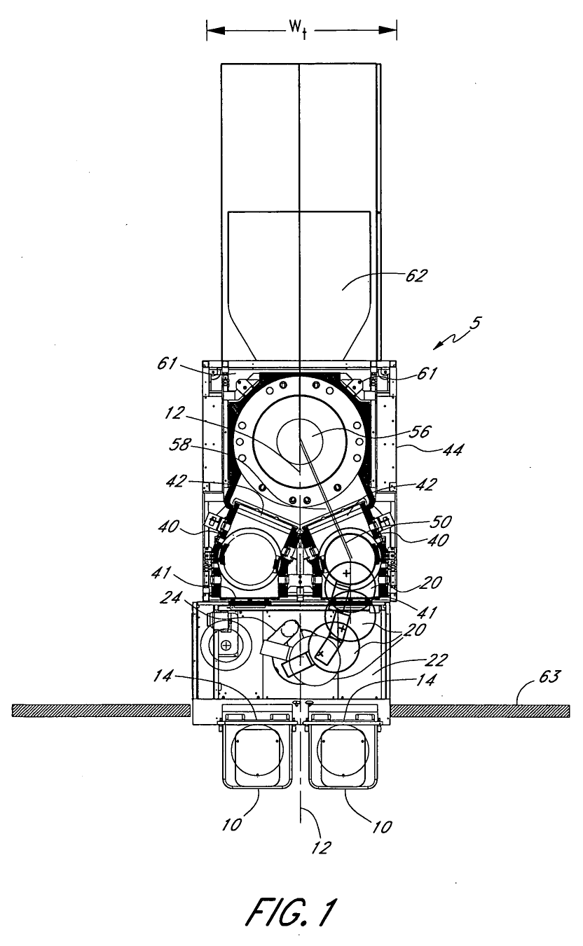

One embodiment of a semiconductor process tool 5 constructed in accordance with a preferred embodiment of the invention is illustrated by reference to FIGS. 1-6. FIG. 1 is a schematic overhead plan view showing a section of a semiconductor process tool 5, constructed in accordance with a preferred embodiment of the present invention. Referring now to FIG. 1, a transport cassette, preferably a FOUP 10, is removably docked with a docking port 14. In a preferred embodiment, as shown in FIG. 1, there are two FOUPs 10, each docked with a docking port 14.

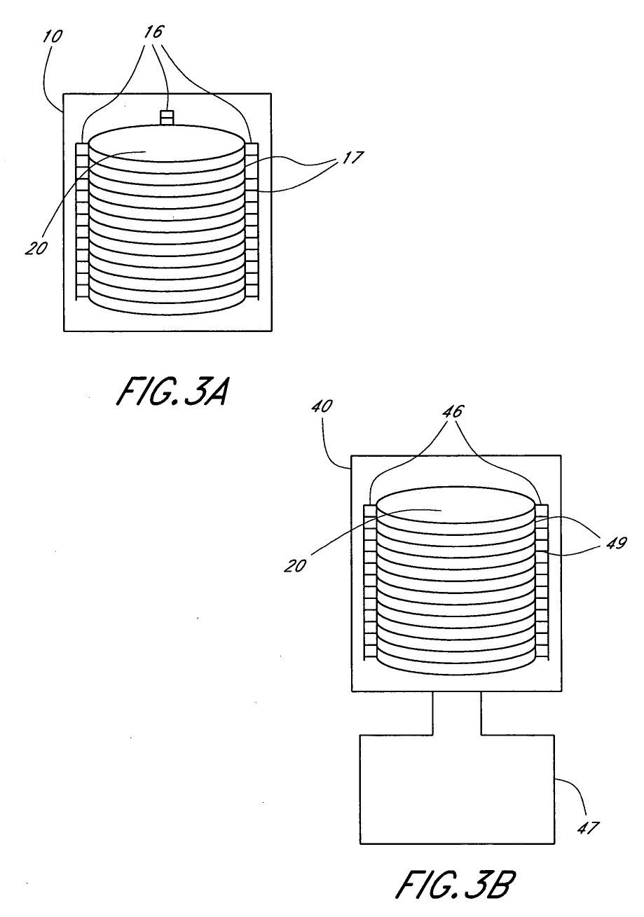

Interior to the FOUP 10 is preferably a cassette rack 16 with individual slots 17, as shown in FIG. 3A. Each slot 17 is capable of holding a wafer 20. In a preferred embodiment, the cassette rack 16 holds 25 wafers 20. Each FOUP 10 is joined with a first wafer handling chamber, preferably an atmospheric front end (AFE) module 22 as shown in FIG. 1. The AFE module 22 is configured to have a laminar purge flow for greater purity but to operate at slightly higher than standard atmospheric pressure. Preferably, the FOUP 10 is also selectively separated from module 22 by FOUP doors (not shown). While illustrated as an enclosed chamber, he skilled artisan will appreciate that, in other arrangements, the AFE may be replaced by a simple platform open to the clean room.

In the AFE module 22 is a robot arm 24 that preferably has an end effector. The end effector comprises one or more substrate supports and is capable of holding a wafer 20 for transport from a FOUP 10 to one of the loadlock chambers 40. The robot arm 24 is configured to be capable of accessing wafers 20, which are located in the cassette rack 16, through one of the docking ports 14.

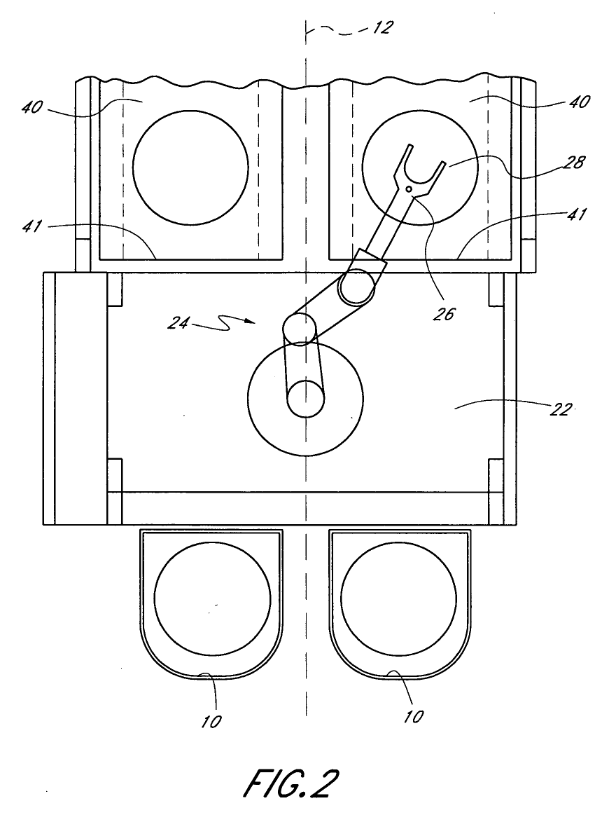

In an embodiment, the end effector of the robot arm 24 is a vacuum paddle, as shown in FIG. 2. A vacuum port 26 is positioned at the base of a horseshoe-shaped section on the end effector, as illustrated in FIG. 2. In alternate arrangements, the end effector could be a fork, paddle, edge grip, vacuum or Bernoulli wand, among other configurations readily apparent to the skilled artisan.

Preferably, the robot arm 24 is centered along the centerline 12 in the AFE module 22, as shown in FIG. 2. Centerline 12 runs down the center of the semiconductor process tool 5 in the longitudinal direction of the system, as shown in FIGS. 1 and 2. The robot base is preferably fixed within the AFE module 22 and the end effector of the robot arm 24 is movable along a trajectory to transfer wafers from the FOUPs 10 to the loadlock chambers 40, as shown in FIG. 1. Preferably, the trajectory of the end effector of the robot arm 24 is in the shape of an arc. FIG. 2 shows a typical position of the robot arm 24 when it is loading a wafer 20 into the right loadlock chamber 40. Typically, the end effector has support pads 28 on the ends, as shown in FIG. 2. The support pads 28 are provided so that there are limited points of contact between the end effector and the wafer 20 to prevent damage to the backside of the wafer 20.

As shown in FIG. 2, the robot arm 24 is preferably a multi-joint arm. The skilled artisan will appreciate that other types of robot or transfer arms may be used instead of a multi-joint arm. Alternatively, a frog-leg arm, for example, may be used instead. In an alternative arrangement, the end effector of the robot arm 24 comprises a Bernoulli wand, which operates on the Bernoulli principle (which will be described in more detail below).

The robot arm 24 is configured to allow access to loadlock chambers 40. With reference to FIG. 1, in a preferred embodiment, two loadlock chambers 40 are also adjoined to the AFE module 22. The loadlock chambers 40 are preferably arranged side-by-side at an angle to each other, as shown in FIG. 1. Each of the loadlock chambers 40 can be accessed by the end effector of the robot arm 24 via a gate valve or door 41. The gate valves 41, when closed, isolate the loadlock chambers 40 from the AFE module 22 to prevent cross-contamination between the modules. In a preferred embodiment, the robot arm 24 travels along an arcuate path or trajectory to transfer a wafer 20 from the AFE module 22 to the gate valve 41. While the entire path is arcuate, the end segment from through the gate valve 41 and into the loadlock chamber 40 is nearly linear, as shown in FIG. 1. The curvature is interpolated by the robot control software from user input of multiple points (e.g., five) along the desired trajectory, and thus is typically not.

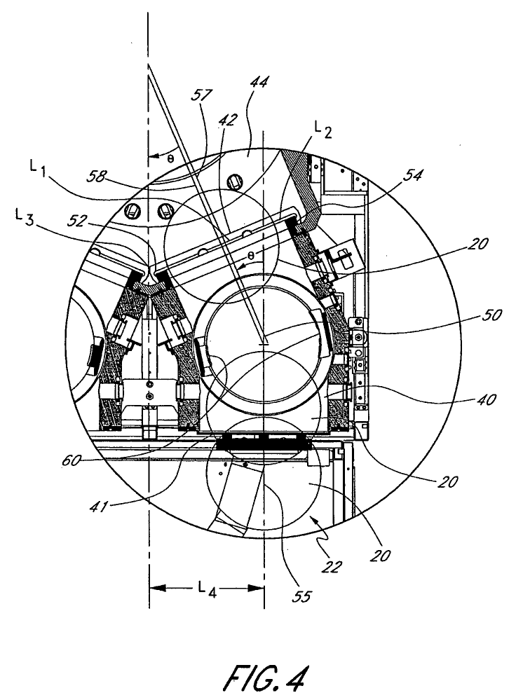

The loadlock chambers 40 are located to serve as a selectively closeable passageway between the AFE module 22 and a second wafer handling chamber (WHC) 44, with a gate valve or door 41, 42 on each end of the loadlock chambers 40, as shown in FIGS. 1 and 4. Thus, the loadlock chambers 40 can be selectively isolated on the front end from the AFE module 22, which is typically at atmospheric pressure, and on the rear end from the WHC 44. For convenience, the gate valve 41 at the front end can be referred to as an inlet and the gate valve 42 at the rear or back end can be referred to as an outlet, although it will be understood that, in practice, wafers can be passed in both directions. The loadlock chambers 40 are couple to and communicate internally with both the AFE module 22 and the WHC 44 by means of the gate valves 41, 42, which prevent cross-contamination between the chambers when closed. The loadlock chambers 40 may also be isolated from the atmospheric ambient gas by being evacuated by, for example, a vacuum suction mechanism, and the loadlock chambers 40 can be filled with an inert gas, such as N₂, for example, by means of a gas supply mechanism.

The loadlock chamber 40 is typically used to facilitate transfer of wafers 20 between the AFE module 22 at atmospheric pressure and the WHC 44, which can have a vacuum environment. Even without a differential in operating pressure, use of loadlocks and purging help maintain purity of the back end processing environment. It should also be understood that the loadlock chamber 40 can be advantageously used as a pre-processing station or a post-processing station when heating/cooling mechanisms and/or connections to process gases are added to the loadlock chambers, thereby eliminating the need for buffer stations and minimizing the size of the process tool 5 footprint.

FIG. 1 illustrates exemplary relative positions of the robot arm 24 in operation for accessing the loadlock wafer rack in the loadlock chamber 40. As shown in FIG. 1, the robot arm 24 preferably travels along an arcuate path to access the loadlock rack. Although the robot arm is shown in FIG. 1 to access the loadlock rack in the right loadlock chamber 40, the skilled artisan will understand that the robot arm 24 is capable of accessing wafers 20 in either of the loadlock chambers 40. Similarly, the robot arm 24 preferably travels along an arcuate path to access the loadlock rack 46 in the left loadlock chamber 40.

In a preferred embodiment, a loadlock rack 46, comprising side combs 60, is inside each of the loadlock chambers 40. With reference to FIG. 3B, the loadlock rack 46 is preferably comprised of individual slots 19 or shelves, each capable of holding a single wafer 20. In a preferred embodiment, the individual slots 19 are spaced to allow access by a Bernoulli wand to transfer individual wafers 20 to and from the slots 19. Preferably, the loadlock rack 46 is designed to hold 25 wafers 20. In addition, although the FOUP 10 is preferably designed to hold a standard FOUP load of 25 wafers, in other embodiments, the combs 60 may be designed to hold more or less than 25 wafers. FIG. 3B also shows an elevator mechanism 47 designed to allow robot access to each slot 19 through the minimal openings of the gate valves 41, 42.

Although in preferred embodiments the cassette (FOUP) rack and loadlock rack support individual wafers by using slots, it should be understood that alternate embodiments employ shelves or other suitable wafer support structures that facilitate the desired relative spacing between wafers. Although the end effector of the atmospheric robot arm 24 is described as a paddle for fitting between the support combs of the loadlock rack 46 and lifting individual wafers from below, the skilled artisan will appreciate that other types of end effectors, such as, for example, edge grip, Bernoulli wand, etc., can be employed with a variable pitch mechanism.

FIG. 4 is an enlarged top plan view of the right loadlock chamber 40, and shows the transfer path of a wafer 20 from the AFE module 22 through the loadlock chamber 40 and into the WHC chamber 44 in a preferred embodiment. The rear walls of the loadlock chambers 40 are connected to the front end wall of the WHC 44. As shown in FIGS. 1 and 4, the loadlock chambers 40 are in communication with the WHC 44 via the gate valves 42.

As shown in FIG. 1 the loadlock chambers 40 are arranged symmetrically about centerline 12, and the left loadlock chamber 40 is preferably essentially a mirror image of the right loadlock chamber 40 and is similarly configured. Thus, the description of the right loadlock chamber 40 will also apply to the left loadlock chamber 40. Although two loadlock chambers 40 are described in a preferred embodiment of the present invention, the skilled artisan will appreciate that one or three or more loadlock chambers may be used instead.

FIG. 4 also shows the configuration of the wafer combs 60 of the loadlock rack 46 within the loadlock chamber 40. The wafer combs 60 are positioned to allow the wafer 20 to follow an angled or bent wafer path 58 through the loadlock chamber 40. Preferably, there are wafer combs 60 on the left side and on the right side of the loadlock chamber 40. In a preferred embodiment, the wafer combs 60 include 25 slots capable of storing 25 wafers 20. For example, stacks of five loadloack racks, each accommodating five wafers, are located in each loadlock chamber 40.

The wafer combs 60 are preferably positioned at a point in the loadlock chamber 40 where the wafer path 58 is angled, as shown in FIG. 4. The wafer path 58 is angled such that the wafer 20 enters the loadlock chamber 40 from the AFE module 22 along a front gate valve axis 55 and exits the loadlock chamber 40 into the WHC chamber 44 along a rear gate valve axis 50. The two axes, as shown in FIG. 4, form a suitable acute angle θ where they meet, such that the semiconductor process tool 5 can have a desired overall width wₜ.

As illustrated in FIG. 1, the left loadlock chamber 40 and the right loadlock chamber 40 are mirror images of each other, and are positioned at an angle to each other, as shown in FIG. 1. It is advantageous to angle the loadlock chambers 40 so that they both may be accessed by the same robot arm 24 in the AFE module 22, as well as by the same WHC robot 56 in WHC 44. In a preferred embodiment, the angle between the loadlock chambers 40 is defined by the width of the gate valves 42 between the WHC 44 and the loadlock chambers 40. Thus, the angle between the loadlock chambers 40 and the width of the gate valves 42 define the overall width of the semiconductor process tool 5. As noted above, it is advantageous to minimize the overall width of the process tool 5.

In a preferred embodiment, the angle θ is between 15° and 30°. More preferably, the angle θ is between 18° and 25°. In a preferred embodiment, the gate valve 42 has a width between 12 inches and 15 inches. More preferably, the gate valve 42 has a width between 13 inches and 13.5 inches. Even more preferably, the gate valve is approximately 13.2 inches wide. Preferably the overall width of the tool is between 36 inches and 50 inches, and more preferably 42 inches and 48 inches.

In a preferred embodiment having gate valves 42 that are 13.2 inches wide, an angle θ of about 23°, and the overall width of the semiconductor process tool 5 is less than 46 inches. A loadlock chamber 40 in a process tool 5 having such a width may be configured to be coupled to a module, such as an AFE module, having a predetermined width to process 12 inch (300 mm) wafers.

With reference to FIG. 4, a preferred embodiment, the distance L3 between the loadlock chambers 40 can be reduced by a few methods to reduce the overall width of the semiconductor process tool 5. For example, the gate valves 42 can be positioned as close to each other as possible, thereby minimizing clearance L3. As shown in FIG. 4, the inner walls 52 of the two loadlock chambers 40 abut each other in the vicinity of the gate valves 42, such that the clearance L3 is zero or substantially zero.

Another way to reduce the angle between the loadlock chambers 40 is to alter the wafer transfer path 58 through the loadlock chambers 40. The wafer transfer path 58 can be arranged such that the wafer 20 is biased toward one side of the gate valve 42 opening as it passes through the gate valve 42. In other words, the center of the wafer 20 passes closer to the inner wall 52 than the outer wall 54 as it passes through the gate valve 42.

The center line 50 of the gate valve 42 openings is marked in FIG. 4 to show that the wafer transfer path 58 is not centered within the loadlock chamber 40 with respect to the inner wall 52 and the outer wall 54 of the gate valve 42. As illustrated in FIG. 4, the wafer path 58 is offset from, and in the illustrated embodiment parallel with, the center line 50 of the gate valve 42 openings. As shown in FIG. 4, the wafer 20/gate valve 42 clearance L1 on the inner wall 52 side is smaller than the wafer 20/gate valve 42 clearance L2 on the outer wall 54 side. In a preferred embodiment, the wafer 20/gate valve 42 clearance L1 on the inner wall 52 side is in the range of 0.15 inch to 0.35 inch. More preferably, the wafer 20/gate valve 42 clearance L1 on the inner wall 52 side is approximately 0.25 inch. Preferably, the wafer 20/gate valve 42 clearance L2 on the outer wall 54 side is in the range of 0.8 inch to 1.2 inches. More preferably, the wafer 20/gate valve 42 clearance L2 on the outer wall 54 side is approximately 1.06 inches, more than four times the clearance on the inner wall 52 side. Clearance L2 is preferably at least twice the length of clearance L1.

By adjusting the outer combs inwardly, such that the wafer path 58 is inwardly offset from the rear gate valve axis 50, and further adjusting the wafer path 58 inwardly relative to the gate valve centerline or axis 50, the width of the system with two loadlock chambers 40 can be reduced to couple with a standardized WHC 44 while still employing two loadlock chambers 40. At the same time, the footprint of the process tool 5 may also be reduced. While illustrated with the wafer path 58 parallel to the rear gate valve axis 57, it will be understood that the path 58 and axis 57 can be angled to one another, in addition to being offset.

Thus, the selected comb 60 positions and consequent wafer path 58 enable the right loadlock chamber 40 and the left loadlock chamber 40 to be mounted such that the clearance L3 between the gate valves 42, as shown in FIG. 4, is minimal. The smaller the clearance L3, the closer the loadlock chambers 40 can be mounted. L4 in FIG. 4 represents the distance L4 between the centerline 55 of the inlet gate valve 41 and the centerline of the tool, thus representing half the distance between the inlet centerlines of the two loadlocks 40. A minimal distance L4 is important to reduce the overall width of the semiconductor process tool 5. Reducing the clearance L3 (and thus the distance L4) is also important to fit the loadlock chamber 40 with available AFE modules 22 and WHC's 44 having a predetermined width.

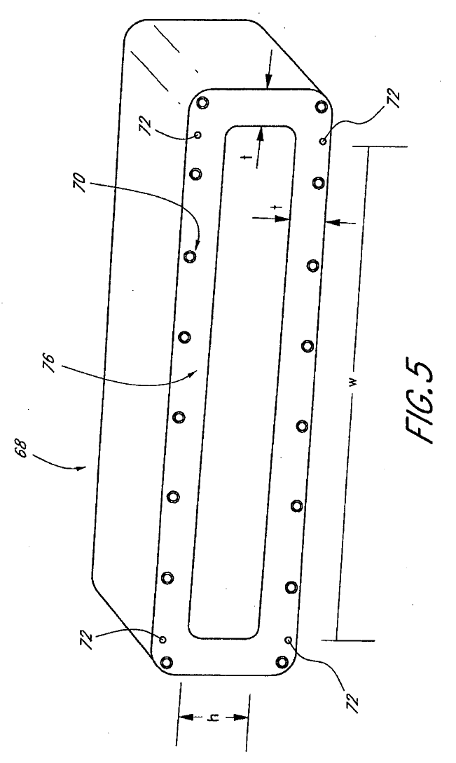

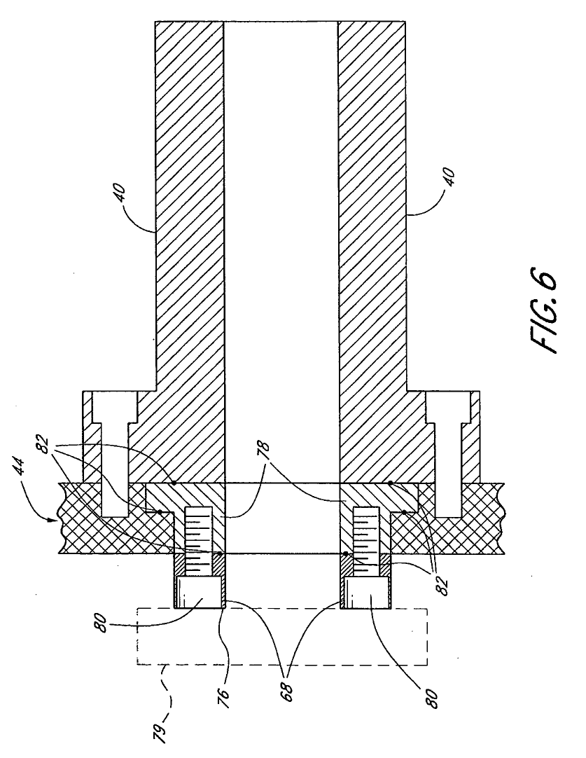

With reference to FIGS. 5 and 6, in an embodiment, gate valve seats 68 are used for the gate valves 42 between the loadlocks 40 and the WHC 44. FIG. 5 is a front perspective view of a gate valve seat 68 that is manufactured by VAT, Inc. of Woburn, Mass. One such seat 68 is preferably positioned at each of the gate valve 42 openings.

Typically, gate valves are positioned or sandwiched between loadlock chambers 40 and the WHC 44. The use of gate valve seats in general provides a readily replaceable protective sealing surface for engagement with the valve body or door between chambers, formed of a material selected to resist particle generation from gate valve opening and closing and scratches from accidental wafer dropping and breakage. In the illustrated embodiment, however, the gate valve seat 68 is positioned by a gate valve insert 78 in a manner that makes it possible to reduce the overall dimensions of the process tool 5. Because the gate valves seats 68 and gate valve inserts 78 are positioned within the confines of the WHC 44 and its wall, rather than between the loadlock chambers 40 and the WHC 44, the overall length of the process tool 5 can be reduced because the WHC 44 can directly abut the loadlock chamber 40, as shown in FIG. 6. Similarly, the use of insert style gate valves allows the overall width of the process tool 5 to be reduced as well because the clearance L3 and thus the distance L4 can be minimized even more. Moreover, the use of the insert 78 facilitates proper alignment of the gate valve seat 68 relative to the gate valve body or door, as will be better understood from the discussion below.

A face 76 on one side of the gate valve seat 68 is visible from within the WHC 44. In a preferred embodiment, the gate valve seat 68 opening has an inner width w of approximately 13.2 inches wide and a height h of approximately two inches. A gate valve opening of this size is capable of allowing a 12 inch (300 mm) wafer 20 to pass through the opening even with the offset wafer path of the preferred embodiment. The outer dimensions of the gate valve seat 68 are preferably about 14.6 inches wide and approximately 3.4 inches high. Thus, the thickness t of the gate valve seat 68 is approximately 1.4 inches.

FIG. 6 is a cross-sectional side view showing the gate valve seat 68 in relation to the loadlock chamber 40 and the WHC 44. A gate valve body or door 79 is also shown in phantom. As shown in FIG. 6, the gate valve seat 68 is positioned adjacent the wall of the WHC 44. As shown in FIG. 6, there is a gate valve insert 78 for attaching the gate valve seat 68 to the WHC 44 wall. FIG. 6 also shows seals 82 where the gate valve insert 78 is sealed to the gate valve seat 68 as well as the WHC 44 wall in a preferred embodiment. As understood by the skilled artisan, the WHC 44 wall preferably has features to accommodate the sealing configuration.

As shown in FIG. 5, in a preferred embodiment, the face 76 of the insert style gate valve 68 preferably has about 16 blind tapped holes 70. Screws 80 are placed through the holes 70 to attach the gate valve seat 68 to the insert 78, which is positioned within the wall of the WHC 44, as shown in FIG. 6. There are also preferably dowel pin locating holes 72, as shown in FIG. 5. The pin locating holes 72 are for alignment of the gate valve seat 68 with the insert 78.

In a preferred embodiment, the insert 78 has a plurality of tapped holes that are each configured to receive a screw 80. The insert 78 has a substantially L-shaped cross-section and fits within a mating step defined in an opening of the WHC 44 wall, as shown in FIG. 6. The insert 78 is preferably made of stainless steel. The insert 78 can comprise a single rectangular ring, matching the shape of the seat 68, or can comprise separate upper and lower members.

The insert 78 allows the insert style gate valve 68 to be attached to the WHC 44 wall more easily. The insert 78 is positioned within the WHC 44 wall, as shown in FIG. 6. The use of the inserts 78 also provides manufacturing benefits. The inserts 78 make it possible to hold very tight tolerances (e.g., within 5 milli-inches, more preferably within 2 milli-inches) for the gate valve seats 68. Also, in case of any damage to a gate valve seat 68, the gate valve seat 68 can simply be replaced. The skilled artisan will appreciate that, during assembly, the insert is mounted within the opening of the WHC 44 wall from the outside; while the gate valve seat 68 is preferably mounted from within the WHC 44. In particular, once the gate valve door mechanism has been positioned at the bottom of the WHC 44, the precision step of aligning the insert 78 relative to the gate valve body is easily arranged from outside the WHC 44, for example by the use of pre-measured L-brackets on the outer surface of the WHC 44. The insert 78, in turn, dictates alignment of the gate valve seat 68, such that the seat 68 can be readily aligned relative to the gate valve body or door, without requiring precision alignment steps for boring holes from the inside of the WHC 44. As will be appreciated by the skilled artisan, the tight confines of the WHC 44 make such operations difficult.

The operation of transferring a wafer 20 from a FOUP 10 to a WHC 44 will be described in detail below. The operation of the embodiment shown in FIG. 1 preferably begins with a FOUP 10 of wafers 20 arriving at the docking port 14 of an AFE module 22. A robot arm 24 located inside the AFE module 22 preferably moves the end effector through an arcuate path to the docking port 14 and locates the end effector proximate to a cassette rack 16 contained within the FOUP 10. The robot arm 24 then removes the wafer 20 from the cassette rack 16. In preferred embodiments, after unloading, the wafer robot arm 24 returns to the cassette rack 16 for the number of cycles required to transfer all of the wafers 20 from the FOUP 10 into the tool 5, as described above, and the AFE module 22 is closed in order to minimize contamination.

After a wafer 20 has been transferred from the cassette rack 16 to the AFE module 22, the gate valve 41 between the AFE module 22 and one of the loadlock chamber 40 is opened, and the robot arm 24 places the wafer 20 onto the loadlock rack 46, where it is kept in an inert environment. Preferably, wafers 20 in need of processing are unloaded in the loadlock rack 46 by the robot arm 24. In one embodiment, processed wafers are stored in a loadlock chamber 40 while unprocessed wafers are stored in a separate loadlock chamber 40. The robot arm 24 preferably is programmed to continue to cycle between the cassette rack 16 and the loadlock rack 46 until a loadlock chamber 40 is full. The inlet gas valve 41 is closed and the loadlock chamber 40 is purged and/or pumped down to low pressure. In cases where the WHC 44 operates at low pressure, the loadlock chamber 40 is preferably evacuated through a pumping port to a vacuum level substantially equal to that of the WHC 44. Access between the evacuated loadlock chamber 40 and the WHC 44 is achieved by opening the gate valve 42 between the two chambers while the gate valve 41 between the loadlock chamber 40 and the AFE module 22 remains closed.

Referring to FIG. 1, behind the loadlock chambers 40 is a wafer handling chamber (WHC) 44. A WHC robot 56 is positioned in the WHC 44 to have effective access to both the loadlock chambers 40 and the interior of a process chamber 62. As readily apparent to the skilled artisan, more than one process chamber 62 may be adjacent the WHC 44, and that the WHC robot 56 may be positioned to have effective access to the interiors of all of the individual process chambers 62. The process chambers 62 may be used to perform the same process on wafers. Alternatively, as the skilled artisan will appreciate, the process chambers 62 may each perform a different process on wafers. The processes include, but are not limited to, sputtering, chemical vapor deposition (CVD), etching, ashing, oxidation, ion implantation, lithography, diffusion; and the like. Each process chamber 62 typically contains a susceptor, or other substrate support, for supporting a wafer to be treated within the process chamber 62. The process chambers 62 are typically furnished with a connection to a vacuum pump, a process gas injection mechanism, an exhaust and heating mechanisms. Processes are typically performed in the process chamber 62 at low pressure, ranging from the milliTorr range to 250 Torr.

When unprocessed wafers 20 are loaded into the loadlock chamber 40 by the robot arm 24, the gate valve 41 between the loadlock chamber 40 and the AFE module 22 is closed to isolate the chambers.

The WHC robot 56 preferably individually transfers the unprocessed wafers 20 from the loadlock rack 46 within the loadlock chamber 40 through the opened gate valve 42 and into a process chamber 62 for processing via the WHC 44. More than one wafer can be unloaded into the WHC 44 and temporarily stored at a staging station 61, which can double as a cooling station, in order to increase throughput. Processed wafers 20 are then removed from the process chamber 62 by the WHC robot 56 and returned to the loadlock rack 46 within the loadlock chamber 40. The loadlock chamber 40 is preferably vented to substantially equalize the pressure between the loadlock chamber 40 and the AFE module 22, which is at atmospheric pressure. Then, as noted above, the robot arm 24 preferably transfers wafers 20 back to the cassette rack 16 from the loadlock rack 46.

In preferred embodiments, a clean room wall 63 defines a “gray room” environment to which wafers are not exposed while the cassettes 10 are located on the clean room side of the wall 63, which is cleaner. In an alternate embodiment, the clean room wall 63 may be placed closer to the loadlock chambers 40 or can be completely absent from the fabrication tool setup.

In a preferred embodiment, the end effector of the WHC robot 56 is a Bernoulli wand. In alternative embodiments, the end effector could be, for example, a fork, paddle, edge grip or vacuum wand.

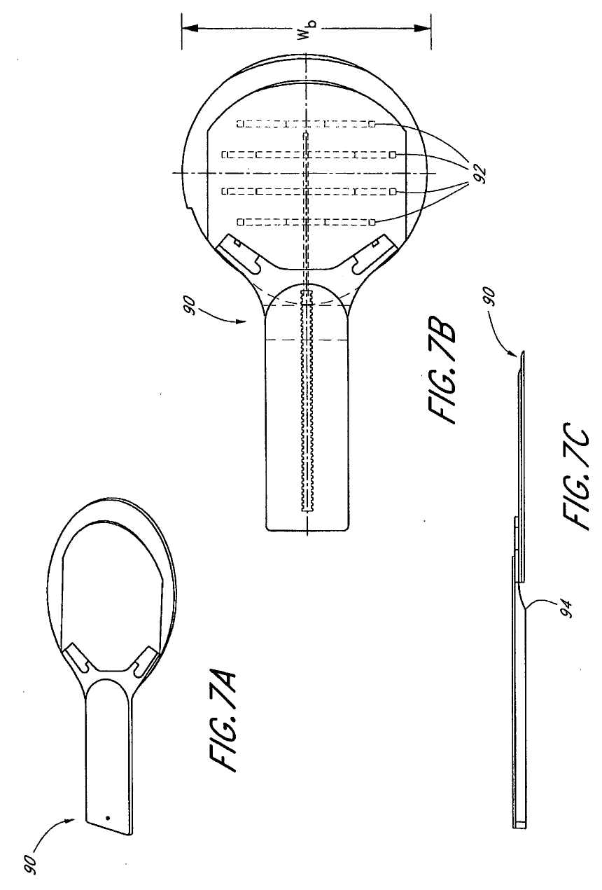

The advantage provided by the Bernoulli wand is that a hot wafer generally does not contact the pickup wand, except perhaps at one or more small edge locators positioned on the underside of the wand. Such a Bernoulli wand is shown in U.S. Pat. No. 5,080,549 to Goodwin, et al., which is hereby incorporated by reference. FIG. 7A is a top perspective view, FIG. 7B is a top plan view, and FIG. 7C is a side view of a Bernoulli wand 90 of a preferred embodiment.

The Bernoulli wand operates on the Bernoulli principle; it provides a plurality of relatively high velocity gas flow streams above the wafer through openings 92 on the underside of the wand, creating a pressure drop across the wafer to draw it upward toward the wand. Jets of inactive gas produce a low pressure zone between the end effector and the wafer 20. The jet streams are normally angled between the vertical and horizontal to create the low pressure zone and create a gas cushion to prevent direct contact between the wafer and the wand. A typical gas for use within a Bernoulli wand is N₂. As shown in FIG. 7C, the Bernoulli wand 90 includes a lower wand foot 94 that prevents the wafer 20 from flowing laterally away from the wand. The wand foot 94 normally extends downwardly below the lower surface of the wafer. The Bernoulli wand typically centers the wafer 20 above the wafer holder (not shown) in the process chamber 62 and then either lowers the wafer 20 onto the wafer holder or permits the wafer 20 to drop thereon. The wafer holder may include a pocket or recess designed to receive the wafer 20. The top surface of the pocket of the wafer holder may include grooves to permit gas between the wafer and the wafer holder to escape around the edges of the wafer 20. Such grooves help to prevent the wafer from sliding horizontally with respect to the wafer holder.

In a preferred embodiment, the Bernoulli wand has a width substantially equal to that of the wafer 20 being transferred. In an embodiment, the width w_{b} of the Bernoulli wand is 12 inches, which is approximately 300.228 mm, or slightly larger than the size of a 300 mm wafer. The Bernoulli wand can be configured such that it travels above the wafer within a slot defined by the combs 60 of the loadlock cassette 46 such that the Bernoulli wand picks up a wafer 20 from above. The Bernoulli wand is preferably made of quartz.

According to an embodiment, the end effector of the WHC robot 56 preferably travels in a straight path to transfer a wafer 20 from either of the loadlock chambers 40 through its gate valve 42 and into WHC 44. In operation of a preferred embodiment, the Bernoulli wand picks up a single wafer 20 in the loadlock chamber 40 and transfers the wafer 20 in a preferably straight path 58 out of the loadlock chamber 40 through the gate valve 42 and into the WHC 44, as shown in FIG. 1. The WHC robot 56 then transfers the wafer 20, directly or by way of a staging station 61, into the process chamber 62 for processing. After a wafer 20 has been processed, the WHC robot 56 then picks up a processed wafer 20 from the process chamber 62 and transfers it back through the WHC 44, directly or via a staging station 61, and into the loadlock chamber 40 via the gate valve 42.

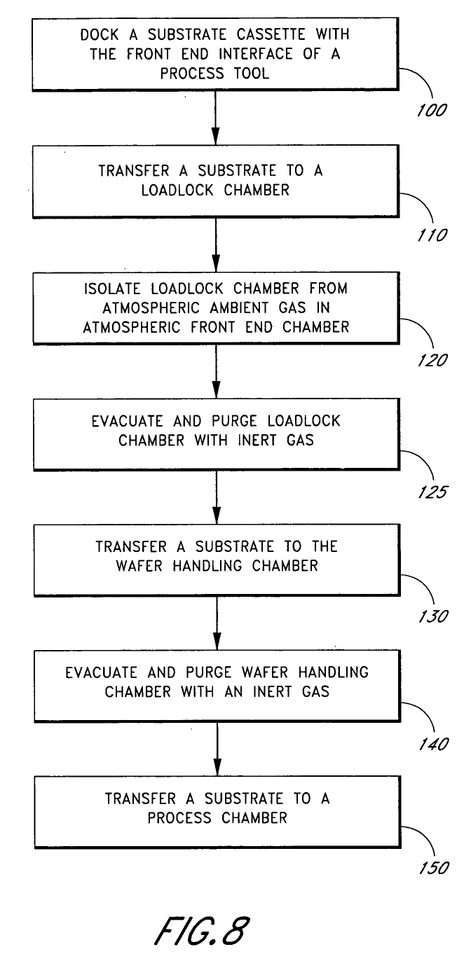

A preferred method of transferring wafers to a process chamber for making integrated circuits is shown in the process flow diagram of FIG. 8, including first docking 100 of a substrate cassette with the front docking ports of a process tool.

One or more of the substrates is then transferred 110 from the front end interface to a loadlock chamber by a robot arm in an AFE module. Preferably, multiple wafers are transferred into the loadlock in sequence. The front end or inlet port of the loadlock chamber is then preferably sealed by closing the gate valve, and the loadlock chamber is isolated 120 from the atmospheric ambient gas in the AFE module. The loadlock chamber can be evacuated by means of a vacuum suction mechanism and/or purged 125 with an inert gas, such as, for example, N₂ gas, by means of a gas supply mechanism.

The gate valve on the rear end or outlet side of the loadlock chamber then opens so that the loadlock chamber and the WHC are in communication. The substrate(s) is (are) then transferred 130 from the loadlock chamber to the WHC by a WHC robot in the WHC. The WHC is preferably continually purged with an inert gas 140, before and after the gate valve is closed.

An individual substrate is then transferred 150 by the WHC robot to a process chamber of a process tool after a gate valve between the WHC and the process chamber is opened. After the gate valve is closed to isolate the process chamber from the WHC, the substrate is treated (e.g., deposition, etching, etc.) in the process chamber.

A feature of certain preferred embodiments of the present invention is that the overall dimensions of the semiconductor processing tool can be minimized. The width across the loadlock chambers can be reduced to allow coupling with an AFE module having a predetermined width. The design of the insert for coupling an available gate valve seat with the WHC wall provides manufacturing benefits as well as reduction in the overall length of the process tool.

Although this invention has been disclosed in the context of certain preferred embodiments and examples, it will be understood by those skilled in the art that the present invention extends beyond the specifically disclosed embodiments to other alternative embodiments and/or uses if the invention and obvious modification thereof. Thus, it is intended that the scope of the present invention herein disclosed should not be limited by the particular disclosed embodiments described above, but should be determined only by a fair reading of the claims that follow.

What is claimed is:

1. A loadlock system, comprising:
a first loadlock chamber having a first port and a second port, wherein a first axis is perpendicular to the first port and a second axis perpendicular to the second port, wherein the first axis and the second axis form an acute angle;
a second loadlock chamber having a third port and a fourth port, wherein a third axis is perpendicular to the third port and a fourth axis is perpendicular to a fourth port, wherein the third axis and the fourth axis form an acute angle;
a first wafer path from the first port to the second port, wherein the first wafer path through at least one of the first and second ports is off-centered with respect to side walls of at least one of the first and second ports; and
a second wafer path from the third port to the fourth port, wherein the second wafer path through at least one of the third and fourth ports is off-centered with respect to side walls of at least one of the third and fourth ports.

2. The loadlock system of claim 1, wherein the first loadlock chamber abuts the second loadlock chamber.

3. The loadlock system of claim 2, further comprising a wafer handling chamber coupled to the first and second loadlock chambers, the wafer handling chamber having a robot capable of accessing substrates within the first and second loadlock chambers.

4. The loadlock system of claim 3, wherein the wafer handling chamber abuts the first and second loadlock chambers.

5. The loadlock system of claim 3, further comprising gate valves mounted a wall of the wafer handling chamber to selectively seal the wafer handling chamber from the first and second loadlock chambers.

6. The loadlock system of claim 5, wherein each of the gate valves comprises:
at least one insert mounted within the wall of the wafer handling chamber; and
a valve seat being positioned within the wafer handling chamber and having a selectively sealable opening, the valve seat being mounted to the at least one insert.

7. A loadlock system, comprising:
a first loadlock chamber having an inlet gate valve and an outlet gate valve at an angle to one another; and
a second loadlock chamber having an inlet gate valve and an outlet gate valve at an angle to one another, wherein a gate valve of the first loadlock chamber is directly adjacent a gate valve of the second loadlock chamber.

8. The loadlock system of claim 7, wherein a wafer path through at least one gate valve is off-centered with respect to a width of the at least one gate valve.

9. The loadlock system of claim 7, further comprising a wafer handling chamber, wherein the wafer handling chamber has a robot capable of accessing substrates through the outlet gate valves of both of the first and second loadlock chambers.

10. The loadlock system of claim 7, wherein the first loadlock chamber has a wafer path therethrough from the inlet gate valve to the outlet gate valve, wherein the wafer path through the inlet gate valve is in a first direction along a first axis and the wafer path through the outlet gate valve is in a second direction along a second axis, wherein the first axis and the second axis form an acute angle.

11. The loadlock system of claim 7, defining a width across both loadlock chambers of between about 42 inches and 48 inches.

12. A loadlock chamber for transferring a semiconductor substrate therethrough, comprising:
an inlet port having a left side wall and a right side wall;
an outlet port having a left side wall and a right side wall; and
a path through the loadlock chamber from the inlet port to the outlet port along which the substrate travels, the path being angled such that the path through the inlet port forms an acute angle with the path through the outlet port, and wherein the path is off-centered with respect to the left side wall and the right side wall of at least one of the inlet and outlet ports.

13. The loadlock chamber of claim 12, wherein the inlet port and the outlet port are selectively sealable to isolate the loadlock chamber.

14. The loadlock chamber of claim 12, wherein the inlet port and the outlet port each comprise gate valves.

15. The loadlock chamber of claim 12, wherein the path is arranged to pass the substrate with a clearance between 0.15 inch and 0.35 inch with respect to one of the right and left side walls and a clearance between 0.8 inch and 1.2 inches with respect to the other of the right and left side walls.

16. A semiconductor process tool for processing a substrate, comprising:
an atmospheric front end module having a robot;
at least one loadlock chamber coupled to the atmospheric front end module, wherein the at least one loadlock chamber has an inlet and an outlet, a first axis perpendicular to the inlet and a second axis perpendicular to the outlet, wherein the first axis and the second axis form an acute angle, and wherein a substrate path through at least one of the inlet and outlet is biased with respect to the width of the at least one of the inlet and outlet;
a wafer handling chamber having a robot, the wafer handling chamber being coupled to the loadlock chamber; and
at least one substrate processing chamber coupled to the wafer handling chamber.

17. The semiconductor process tool of claim 16, comprising two loadlock chambers, wherein the two loadlock chambers are positioned side-by-side adjacent one another.

18. The semiconductor process tool of claim 16, further comprising a gate valve for selectively sealing the wafer handling chamber from the loadlock chamber, wherein the gate valve is mounted to a wall of the wafer handling chamber.

19. The semiconductor process tool of claim 18, wherein the wafer handling chamber directly abuts the loadlock chamber and includes a gate valve seat surrounding an opening for the gate valve, the gate valve seat protruding into the wafer handling chamber.

20. The semiconductor process tool of claim 19, wherein the gate valve seat mounts directly to an insert, the insert fitting within a wall separating the wafer handling chamber from the loadlock chamber.

21. A method of transferring a semiconductor substrate, comprising:
transferring the substrate from a cassette loading dock to a loadlock chamber though a first gate valve; and
transferring the substrate from the loadlock chamber to a transfer chamber through a second gate valve, wherein the loadlock chamber has a substrate path along which the substrate travels from the first gate valve to the second gate valve, wherein the substrate path through at least one of the gate valves is off-centered with respect to a width of an opening of the gate valve.

22. The method of claim 21, wherein the substrate is transferred along an arcuate path from the atmospheric front end module to the loadlock chamber.

23. The method of claim 21, wherein the substrate is transferred along a straight path from the loadlock chamber to the transfer chamber.

24. The method of claim 21, wherein the substrate path is such that the substrate path along a first axis through the first gate valve forms an acute angle with the substrate path along a second axis through the second gate valve.

25. A semiconductor process tool, comprising:
a transfer chamber having a first robot capable of transporting at least one substrate;
a loadlock chamber abutting and in selective communication with the transfer chamber;
a wall separating the loadlock chamber from the transfer chamber, the wall having an opening therein;
an insert aligned within the wall opening; and
a gate valve seat mounted to the insert and extending from the insert into the transfer chamber.

26. The semiconductor process tool of claim 25, wherein the loadlock chamber has an angled substrate path therethrough.

27. The semiconductor process tool of claim 25, wherein the insert and seat define a gate valve opening, including an inner gate valve wall and an outer gate valve wall and having a substrate path therethough, the substrate path being biased toward one of the inner and outer walls.

28. The semiconductor process tool of claim 27, wherein the substrate path is defined in part by the first robot and by a second robot in a front end interface communicating with the loadlock chamber.

29. The semiconductor process tool of claim 28, wherein the substrate path includes a first leg between the front end interface and the loadlock chamber and a second leg between the loadlock chamber and the transfer chamber, the first leg being angled with respect to the second leg.

30. The semiconductor process tool of claim 29, further comprising a second loadlock chamber adjacent the loadlock chamber and communicating with the transfer chamber, the second loadlock chamber being mirror image of the loadlock chamber.

31. The semiconductor process tool of claim 25, wherein the insert is flush with the wall.

32. The semiconductor process tool of claim 25, wherein the insert has an L-shaped cross-section mating with a step in the wall opening.

33. The semiconductor process tool of claim 25, wherein the first robot has an end effector having a width approximately equal that of the at least one substrate.
